(19) United States
(12) Patent Application Publication
(10) Pub. No.: US 2024/0251626 A1
(43) Pub. Date: Jul. 25, 2024

(54) Display Panel, Preparation Method Therefor, and Display Apparatus

(71) Applicant: BOE Technology Group Co., Ltd., Beijing (CN)

(72) Inventors: Kuo SHEN, Beijing (CN); Jing WANG, Beijing (CN); Wenxiu ZHU, Beijing (CN); Shanshan BAI, Beijing (CN); Jianing LIU, Beijing (CN); Hongwei TIAN, Beijing (CN)

(21) Appl. No.: 18/015,724

(22) PCT Filed: Jan. 25, 2022
(86) PCT No.: PCT/CN2022/073703

§ 371 Date: Jan. 12, 2023

(51) Int. Cl. H10K 59/35; H10K 59/12

(52) U.S. Cl. CPC H10K 59/353; H10K 59/1201; H10K 59/351

(57) ABSTRACT

Provided are a display panel, a preparation method thereof, and a display apparatus, which includes a display region, the display region includes at least one functional unit disposed on a substrate, one of the functional units includes a pixel unit and at least one non-display unit, wherein the pixel unit includes at least one sub-pixel, and the orthographic projection of the pixel unit on the substrate does not overlap the orthographic projection of the at least one non-display unit on the substrate.

### CROSS-REFERENCE TO RELATED APPLICATION

The present application is a U.S. National Phase Entry of International PCT Application No. PCT/CN2022/073703, having an international filing date of Jan. 25, 2022, the entire content of which is hereby incorporated by reference.

### TECHNICAL FIELD

Implementations of the present disclosure relate to, but are not limited to, the field of display technologies, and in particular to a display panel, a method for preparing the display panel, and a display apparatus.

### BACKGROUND

Organic Light-Emitting Diode (OLED) is a display lighting technology gradually developed in recent years. Especially in the display industry, it is one of the hot spots in the research field of flat panel display. Compared with Liquid Crystal Display (LCD), it has the advantages of high response, high contrast, low working voltage, thin and light, flexibility, low energy consumption, low production cost, self-luminescence, wide viewing angle and fast response speed.

Fingerprint is unique to everyone. With the development of the market, fingerprint identification technology has become one of the important functions of electronic products. This function has been concerned by many electronic manufacturers and applied in their electronic products, such as mobile phones, tablet computers and smart wearable devices. In this way, before operating the electronic device with fingerprint identification function, the user only needs to touch the fingerprint identification module of the electronic device with his finger to verify the authority, thus simplifying the authority verification process.

When the fingerprint identification structure is located in the display panel, and the position of the fingerprint identification structure coincides with the light emitting region of a pixel unit, the fingerprint identification structure will affect the light emitting of the pixel unit and the display effect of the display panel.

### SUMMARY

The following is a summary of subject matter described herein in detail. The summary is not intended to limit the protection scope of claims.

In a first aspect, an implementation of the disclosure provides a display panel, including a display region, the display region includes at least one functional unit disposed on a substrate, the one functional unit includes a pixel unit and at least one non-display unit, wherein the pixel unit includes at least one sub-pixel, and the orthographic projection of the pixel unit on the substrate does not overlap the orthographic projection of the at least one non-display unit on the substrate.

In an exemplary implementation, in the one functional unit, the pixel unit includes at least one green sub-pixel, at least one blue sub-pixel and at least one red sub-pixel, the minimum distance from the center of the at least one non-display unit to the center of the at least one green sub-pixel is d1, the minimum distance from the center of the at least one non-display unit to the center of the at least one blue sub-pixel is d2, and the minimum distance from the center of the at least one non-display unit to the center of the at least one red sub-pixel is d3, wherein d1, the d2 and the d3 satisfy the relation: d1 is greater than or equal to d2, and d1 is greater than or equal to d3.

In an exemplary implementation, the one functional unit includes a pixel unit and at least two non-display units, the pixel unit includes at least two green sub-pixels, one blue sub-pixel, and one red sub-pixel, and the quantity of the non-display units is the same as the quantity of the green sub-pixels.

In an exemplary implementation, the display panel includes at least two functional units, the at least two functional units are arranged along a first direction of the substrate to form a functional unit row, and in one functional unit row, the centers of non-display units of at least three functional units are in the same straight line in the first direction.

In an exemplary implementation, the one functional unit includes a pixel unit and at least one non-display unit, the pixel unit includes at least one green sub-pixel, at least one blue sub-pixel and at least one red sub-pixel, the display panel includes at least two functional units, the at least two functional units are arranged along a second direction of the substrate to form a functional unit column, in one functional unit column, at least one of a blue sub-pixel, a red sub-pixel and a non-display unit is disposed between at least one green sub-pixel in adjacent functional units.

In an exemplary implementation, the one functional unit includes at least two non-display units, at least two non-display units are arranged along the second direction of the substrate to form a non-display unit column, and a distance between the centers of adjacent non-display units in a non-display unit column is greater than or equal to 0.5 times the functional unit spacing, wherein the functional unit spacing refers to the distance between the centers of adjacent functional units.

In an exemplary implementation, in the one functional unit, the area of the orthographic projection of the at least one non-display unit on the substrate is greater than 100 square microns.

In an exemplary implementation, the non-display unit is an organic photodiode.

In an exemplary implementation, the one functional unit includes a pixel unit and two non-display units, the pixel unit includes two green sub-pixels, one blue sub-pixel and one red sub-pixel, the two green sub-pixels are arranged along the second direction of the substrate to form a green sub-pixel column, the two non-display units are arranged along the second direction of the substrate to form a non-display unit column, in the first direction of the substrate, the blue sub-pixel and the red sub-pixel are located on two sides of the non-display unit column, and in the second direction of the substrate, the green sub-pixel column is located on one side of the non-display unit column, wherein the first direction is different from the second direction.

In an exemplary implementation, the orthographic projection of the non-display unit on the substrate is at least one of a circle, a rectangle, a diamond, and an ellipse.

In an exemplary implementation, the one functional unit includes a pixel unit and one non-display unit, the pixel unit includes two green sub-pixels, one blue sub-pixel and one red sub-pixel, the two green sub-pixels are arranged along the second direction of the substrate to form a green sub-pixel column, in the first direction of the substrate, the blue sub-pixel and the red sub-pixel are located on two sides of the non-display unit, and in the second direction of the substrate, the green sub-pixel column is located on one side of the non-display unit column, wherein the first direction is different from the second direction.

In an exemplary implementation, the one functional unit includes a pixel unit and one non-display unit, the pixel unit includes two green sub-pixels, one blue sub-pixel and one red sub-pixel, the two green sub-pixels are arranged along the second direction of the substrate to form a green sub-pixel column, the red sub-pixel and the green sub-pixel columns are arranged along the first direction of the substrate to form a combined pixel row, in the second direction of the substrate, the combined pixel row and the blue sub-pixels are located on two sides of the non-display unit, wherein the first direction is different from the second direction.

In an exemplary implementation, the orthographic projection of at least one of the green sub-pixel, the blue sub-pixel, the red sub-pixel, and the non-display unit on the substrate is a polygon.

In an exemplary implementation, the one functional unit includes a pixel unit and one non-display unit, the pixel unit includes two green sub-pixels, one blue sub-pixel and one red sub-pixel, the two green sub-pixels are arranged along the second direction of the substrate to form a green sub-pixel column, the non-display unit and the red sub-pixel are arranged in the second direction of the substrate to form a combined pixel column, the green sub-pixel column and the combined pixel column are arranged along the first direction of the substrate, and in the second direction of the substrate, the green sub-pixel column and the combined pixel column are located on the same side of the blue sub-pixel, wherein the first direction is different from the second direction.

In an exemplary implementation, the one functional unit includes a pixel unit and one non-display unit, the pixel unit includes two green sub-pixels, one blue sub-pixel and one red sub-pixel, the two green sub-pixels are arranged along the second direction of the substrate to form a green sub-pixel column, the non-display unit and the blue sub-pixel are arranged along the second direction of the substrate to form a combined pixel column, the green sub-pixel column and the combined pixel column are arranged along the first direction of the substrate, and the green sub-pixel column and the combined pixel column are located on the same side of the red sub-pixel in the second direction of the substrate.

In an exemplary implementation, the one functional unit includes a pixel unit and one non-display unit, the pixel unit includes four green sub-pixels, one blue sub-pixel and one red sub-pixel, two of the four green sub-pixels are arranged along the second direction of the substrate to form a green sub-pixel column a, the other two of the four green sub-pixels are arranged along the second direction of the substrate to form a green sub-pixel column b, the non-display unit and the blue sub-pixel are arranged along the second direction of the substrate to form a combined pixel column, the green sub-pixel column a and the combined pixel column are arranged in the first direction of the substrate, the red sub-pixel is located on one side of the green sub-pixel column a and the combined pixel column in the second direction of the substrate, and the green sub-pixel column b is located on one side of the red sub-pixel and the non-display unit in the first direction of the substrate, wherein the first direction is different from the second direction.

In an exemplary implementation, the one functional unit includes a pixel unit and one non-display unit, the pixel unit includes a green sub-pixel, a blue sub-pixel and a red sub-pixel, the blue sub-pixel and the non-display unit are arranged along the first direction of the substrate to form a first combined pixel row, the red sub-pixel and the green sub-pixel are arranged along the first direction of the substrate to form a second combined pixel row, and the first combined pixel row is located on one side of the second combined pixel row in the second direction of the substrate, wherein the first direction is different from the second direction.

In an exemplary implementation, the display panel includes at least two functional units arranged along the second direction of the substrate to form a functional unit column, in one functional unit column, the first combined pixel rows in adjacent functional units are adjacent in the second direction of the substrate; and/or, the second combined pixel rows in adjacent functional units are adjacent in the second direction of the substrate.

In an exemplary implementation, the one functional unit includes a pixel unit and one non-display unit, the pixel unit includes a green sub-pixel, a blue sub-pixel and a red sub-pixel, in the first direction of the substrate, the green sub-pixel and the red sub-pixel are located on two sides of the non-display unit, and in the second direction of the substrate, the blue sub-pixel is located on one side of the non-display unit, wherein the first direction is different from the second direction.

In an exemplary implementation, the non-display unit includes at least one of a fingerprint identification unit, an iris identification unit, a detection unit, and a sensor.

In a second aspect, an implementation of the present disclosure provides a method for preparing a display panel, including:

forming at least one functional unit on a substrate, wherein the one functional unit includes a pixel unit and at least one non-display unit, the pixel unit includes at least one sub-pixel, the orthographic projection of the pixel unit on the substrate and the orthographic projection of the at least one non-display unit on the substrate are not overlapped.

In a third aspect, an implementation of the present disclosure further provides a display apparatus, including the aforementioned display panel.

Other aspects may be understood upon reading and understanding the drawings and the detailed description.

### BRIEF DESCRIPTION OF DRAWINGS

FIG. 1 is a first top view of a display panel according to an implementation of the present disclosure.

FIG. 2 is a first sectional view of a display panel according to an implementation of the present disclosure.

FIG. 3 is a second top view of a display panel according to an implementation of the present disclosure.

FIG. 4 is a third top view of a display panel according to an implementation of the present disclosure.

FIG. 5 is a fourth top view of a display panel according to an implementation of the present disclosure.

FIG. 6 is a fifth top view of a display panel according to an implementation of the present disclosure.

FIG. 7 is a sixth top view of a display panel according to an implementation of the present disclosure.

FIG. 8 is a seventh top view of a display panel according to an implementation of the present disclosure.

FIG. 9 is an eighth top view of a display panel according to an implementation of the present disclosure.

FIG. 10 is a ninth top view of a display panel according to an implementation of the present disclosure.

FIG. 11 is a first top view of a mask according to an implementation of the present disclosure.

FIG. 12 is a second top view of a mask according to an implementation of the present disclosure.

FIG. 13 is a second sectional view of a display panel according to an implementation of the present disclosure.

### DETAILED DESCRIPTION

The implementations of the present disclosure will be described in detail below with reference to the drawings. It is noted that implementation modes may be implemented in at least two different forms. Those of ordinary skills in the art may easily understand such a fact that implementations and contents may be transformed into various forms without departing from the purpose and scope of the present disclosure. Therefore, the present disclosure should not be explained as being limited to contents described in following implementation modes only. The implementations in the present disclosure and features in the implementations may be combined randomly with each other without conflict.

In the specification, for convenience, wordings indicating orientation or positional relationships, such as “middle”, “upper”, “lower”, “front”, “back”, “vertical”, “horizontal”, “top”, “bottom”, “inside”, and “outside”, are used for illustrating positional relationships between constituent elements with reference to the drawings, and are merely for facilitating the description of the specification and simplifying the description, rather than indicating or implying that a referred apparatus or element must have a particular orientation and be constructed and operated in the particular orientation. Therefore, they cannot be understood as limitations on the present disclosure. The positional relationships between the constituent elements may be changed as appropriate according to directions for describing the various constituent elements. Therefore, appropriate replacements may be made according to situations without being limited to the wordings described in the specification.

In the specification, unless otherwise specified and defined explicitly, terms “mount”, “mutually connect”, and “connect” should be understood in a broad sense. For example, a connection may be a fixed connection, or a detachable connection, or an integrated connection. It may be a mechanical connection or an electrical connection. It may be a direct mutual connection, or an indirect connection through middleware, or internal communication between two components. Those of ordinary skills in the art may understand meanings of the above-mentioned terms in the present disclosure according to situations.

In the present disclosure, “about” refers to that a boundary is defined not so strictly and numerical values within process and measurement error ranges are allowed.

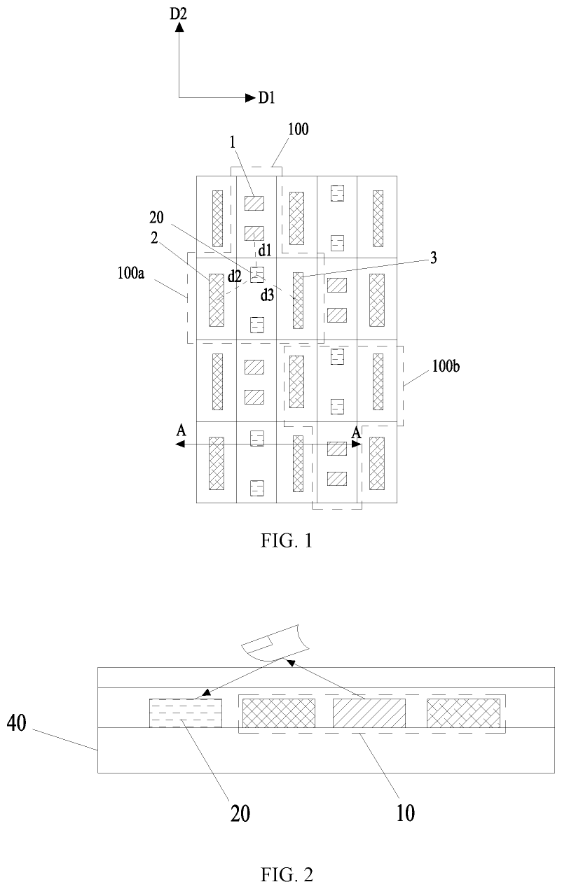

FIG. 1 is a first top view of a display panel according to an implementation of the present disclosure. FIG. 2 is a first sectional view of a display panel according to an implementation of the present disclosure. As shown in FIGS. 1 and 2, an implementation of the present disclosure provides a display panel, including a display region, the display region includes at least one functional unit 100 disposed on a substrate 40, the one functional unit 100 includes a pixel unit 10 and at least one non-display unit 20, wherein the pixel unit 10 includes at least one sub-pixel, and the orthographic projection of the pixel unit 10 on the substrate 40 does not overlap the orthographic projection of the at least one non-display unit 20 on the substrate 40.

In an exemplary implementation, the non-display unit 20 does not have a light emitting function. The non-display unit 20 may include at least one of a fingerprint identification unit, an iris identification unit, a detection unit and a sensor.

In an exemplary implementation, a pixel unit may include at least one Green (abbreviated as G) sub-pixel, at least one Blue (abbreviated as B) sub-pixel, and at least one Red (abbreviated as R) sub-pixel. A green sub-pixel, a blue sub-pixel, and a red sub-pixel of a pixel unit emit green light, blue light, and red light, respectively, thereby causing the display panel to display a picture.

The display panel of the implementation of the present disclosure arranges the non-display unit 20 in the display region, and makes the non-display unit 20 not block the pixel unit, so that the display panel of the implementation of the present disclosure can have other functions besides the light emitting function, such as a fingerprint identification function, through the non-display unit 20. The non-display unit 20 does not occupy the region of the pixel unit and does not affect the emission of sub-pixels such as the green sub-pixel 1, the blue sub-pixel 2, and the red sub-pixel 3, thereby preventing the non-display unit 20 from affecting the display effect of the display panel. Take the non-display unit 20 as the fingerprint identification unit as an example. When the display panel is in the fingerprint identification state, the non-display unit 20 can recognize the intensity of light reflected by a finger, thereby recognizing a fingerprint.

In an exemplary implementation, the pixel unit in the display panel of the implementation of the present disclosure may be an Organic Light-Emitting Diode (OLED for short), it can also be Light-Emitting Diode (LED for short) or Micro LED, and it can also be other types of light emitting devices or light transmitting devices (such as color film). Among the various types of pixel units mentioned above, organic light-emitting diodes have smaller volume, low working voltage, thinness, flexibility, low energy consumption, low production cost, self-luminescence and the like.

In an exemplary implementation, the non-display unit 20 in the display panel of the implementation of the present disclosure may be a fingerprint identification unit. The fingerprint identification unit can be a capacitive fingerprint identification unit, an optical PIN, and an Organic Photo Diode (OPD). Among the various types of the fingerprint identification unit, the organic photodiode has high light responsiveness, can achieve high-pixel full-screen fingerprint identification, has narrow response wavelength, and is not easily affected by ambient light.

Take the non-display unit 20 as the fingerprint identification unit as an example. As shown in FIGS. 1 and 2, one functional unit 100 includes one pixel unit 10 and one non-display unit 20 which may employ an organic photodiode. One pixel unit 10 includes one green sub-pixel 1, one blue sub-pixel 2, and one red sub-pixel 3. The orthographic projection of the pixel unit 10 on the substrate does not overlap the orthographic projection of at least one non-display unit 20 on the substrate. When the display panel of the implementation of the invention carries out fingerprint identification, at least one of the green sub-pixel 1, the blue sub-pixel 2, and the red sub-pixel 3 of the pixel unit 10 emits light emitted in the finger direction. Light is emitted to fingerprints, reflected by the fingerprint to form reflected light emitted toward the non-display unit 20, the non-display unit 20 detects the light reflected by the fingerprint, and the height fluctuation of the fingerprint will have reflected light with different intensities, so that different fingerprint appearances will be distinguished by the non-display unit 20, thereby achieving the fingerprint identification operation in the display region of the display panel.

In an exemplary implementation, the material of the substrate includes glass, plastic, or flexible substrate material. The flexible substrate material includes one or more of polyimide (PI), polyethersulfone (PES), polyacrylate (PAR), polyetherimide (PEI), polyethylene naphthalate (PEN), polyethylene terephthalate (PET), polyphenylene sulfide (PPS), Polyallylate, polycarbonate (PC), cellulose triacetate (TAC), cellulose acetate propionate (CAP) or Acrylamide. Because polyimide is one of the organic polymer materials with the best comprehensive performance, the flexible material has good optical, chemical resistance, water and oxygen resistance and other properties, therefore, the material of the substrate in the display panel of this implementation can adopt polyimide.

In an exemplary implementation, one functional unit 100 includes a pixel unit and at least two non-display units 20, and the pixel unit includes at least two green sub-pixels 1, one blue sub-pixel 2, and one red sub-pixel 3, and the quantity of the non-display units 20 is the same as the quantity of the green sub-pixels 1.

In an exemplary implementation, as shown in FIG. 1, the display panel according to an implementation of the present disclosure includes at least two functional units 100, the at least two functional units 100 are arranged along a first direction D1 of the substrate to form a functional unit row, and in one functional unit row, the centers of non-display units 20 of at least three functional units are in the same straight line in the first direction D1, thereby ensuring the functional effect of the non-display units 20.

In an exemplary implementation, one functional unit 100 includes a pixel unit and at least one non-display unit 20, the pixel unit including at least one green sub-pixel 1, at least one blue sub-pixel 2 and at least one red sub-pixel 3. A display panel of an implementation of the present disclosure includes at least two functional units 100, at least two functional units 100 are arranged along the second direction D2 of the substrate to form a functional unit column, in a functional unit column, at least one of a blue sub-pixel 2, a red sub-pixel 3, and a non-display unit 20 is provided between at least one green sub-pixel 1 in at least two functional units 100, so that in a functional unit column, the green sub-pixels 1 in adjacent functional units 100 are far away, thereby providing a display effect. For example, in a functional unit column, a non-display unit 20 is provided between at least one green sub-pixel 1 in adjacent functional units, as shown in FIG. 1.

In an exemplary implementation, a of the functional unit in a display panel of an implementation of the present disclosure includes at least two non-display units 20, at least two non-display units 20 are arranged along the second direction of the substrate to form a non-display unit column, and a distance between the centers of adjacent non-display units 20 in a non-display unit column is greater than or equal to 0.5 times of the functional unit spacing. The functional unit spacing refers to the distance between the centers of adjacent functional units. For example, in a functional unit row, the spacing of the centers of adjacent functional units in the first direction of the substrate; alternatively, in a functional unit column, the spacing of the centers of adjacent functional units in the second direction of the substrate.

In an exemplary implementation, the display panel includes at least two functional units, the at least two functional units are arranged along a first direction of the substrate to form a functional unit row, and in one functional unit row, the centers of non-display units of at least three functional units are in the same straight line in the first direction.

In an exemplary implementation, one functional unit 100 includes a pixel unit and at least one non-display unit 20, the pixel unit including at least one green sub-pixel 1, at least one blue sub-pixel 2 and at least one red sub-pixel 3. In the one functional unit, the minimum distance from the center of the at least one non-display unit to the center of the at least one green sub-pixel is d1, the minimum distance from the center of the at least one non-display unit to the center of the at least one blue sub-pixel is d2, and the minimum distance from the center of the at least one non-display unit to the center of the at least one red sub-pixel is d3, wherein d1, the d2 and the d3 satisfy the relation: d1 is greater than or equal to d2, and d1 is greater than or equal to d3.

In an exemplary implementation, in the one functional unit, the area of the orthographic projection of the at least one non-display unit on the substrate is greater than 100 square microns, thereby improving the fingerprint identification effect.

In an exemplary implementation, as shown in FIG. 1, a functional unit 100 includes a pixel unit including two green sub-pixels 1, a blue sub-pixel 2, and a red sub-pixel 3, and two non-display units 20. Two green sub-pixels 1 are arranged along the second direction D2 of the substrate to form a green sub-pixel column, the two non-display units 20 are arranged along the second direction D2 of the substrate to form a non-display unit column, in the first direction D1 of the substrate, the blue sub-pixel 2 and the red sub-pixel 3 are located on two sides of the non-display unit column, and the centers of the blue sub-pixel 2, the red sub-pixel 3 and the non-display unit column are in a straight line in the first direction D1 of the substrate. In the second direction D2 of the substrate, the green sub-pixel column is located on one side of the non-display unit column, and the center of the green sub-pixel column and the center of the non-display unit column are in a straight line in the second direction D2 of the substrate. Herein, the first direction D1 is different from the second direction D2. In an example, the first direction D1 is provided perpendicularly to the second direction D2.

In some implementations, the centers of two green sub-pixels in the green sub-pixel column and the centers of two non-display units in the non-display unit column may be in the same straight line in the second direction D2 of the substrate.

In an exemplary implementation as shown in FIG. 1, the display panel of the implementation of the present disclosure includes at least two functional units 100. At least two functional units 100 are arranged along the second direction D2 of the substrate to form a column of functional units 100, in which a non-display unit 20 is provided between at least one green sub-pixel 1 in adjacent functional units 100.

In an exemplary implementation, as shown in FIG. 1, the display panel of the implementation of the present disclosure may include at least one first functional unit 100a and at least one second functional unit 100b, which are arranged along the first direction D1 of the substrate to form a repeating unit. In a repeating unit, in the second direction D2 of the substrate, the green sub-pixel column in the first functional unit 100a is located on the first side of the non-display unit column, and the center of the green sub-pixel column in the first functional unit 100a is in a straight line with the center of the blue sub-pixel 2, the center of the red sub-pixel 3 and the center of the non-display unit column in the second functional unit 100b in the first direction D1 of the substrate. The green sub-pixel column in the second functional unit 100b is located on the second side of the non-display unit column, and the center of the green sub-pixel column in the second functional unit 100b is in a straight line with the center of the blue sub-pixel 2, the center of the red sub-pixel 3 in the first functional unit 100a and the center of the non-display unit column in the first direction D1 of the substrate. In the second direction D2 of the substrate, the first side of the non-display unit column and the second side of the non-display unit column are respectively located on opposite sides of the non-display unit column.

In an exemplary implementation, as shown in FIG. 1, a first functional unit 100a is arranged in a pyramid, a second functional unit 100b is arranged in an inverted pyramid, and a first functional unit 100a and a second functional unit 100b are arranged in combination to form a rectangular pattern of repeating units. The display panel of an implementation of the present disclosure may include at least two repeating units arranged along the first direction D1 of the substrate to form a repeating unit row, and at least two repeating unit rows arranged along the second direction D2 of the substrate.

FIG. 13 is a second sectional view of a display panel according to an implementation of the present disclosure. FIG. 13 may be a sectional view taken along A-A direction in FIG. 1. In an exemplary implementation, as shown in FIG. 13, the green sub-pixel 1, the blue sub-pixel 2, the red sub-pixel 3 and the non-display unit 20 are arranged in the same layer in the display panel according to the implementation of the present disclosure. A display panel according to an implementation of the present disclosure includes a substrate and a drive structure layer and a functional structure layer disposed on the substrate. The drive structure layer is connected with the functional structure layer. The drive structure layer includes at least one thin film transistor, and one thin film transistor includes an active layer, a gate electrode and a source-drain electrode disposed on a substrate. The functional structure layer includes a green sub-pixel 1, a blue sub-pixel 2, a red sub-pixel 3, and a non-display unit 20. The green sub-pixel 1, the blue sub-pixel 2, and the red sub-pixel 3 each include a first electrode, a second electrode, and a light emitting layer disposed between the first electrode and the second electrode, and the non-display unit 20 includes a third electrode, a fourth electrode, and an organic functional layer disposed between the third electrode and the fourth electrode. The first electrodes in the green sub-pixel 1, the blue sub-pixel 2, the red sub-pixel 3 and the third electrode in the non-display unit 20 are arranged in the same layer, that is, they can be prepared by the same preparation process using the same material. The second electrodes in the green sub-pixel 1, the blue sub-pixel 2, the red sub-pixel 3 and the fourth electrode in the non-display unit 20 can be integrally molded using the same material through the same preparation process.

In an exemplary implementation, the blue sub-pixel 2, the red sub-pixel 3, and the green sub-pixel 1 each further include a hole injection layer, a hole transport layer, an electron transport layer, and an electron injection layer. Specifically, the hole injection layer is arranged on the side of the first electrode away from the substrate; the hole transport layer is arranged on the side of the hole injection layer away from the substrate; the emitting layer is arranged on the side of the hole transport layer away from the substrate; the electron transport layer is arranged on the side of the emitting layer away from the substrate; the electron injection layer is arranged on the side of the electron transport layer away from the substrate; and the second electrode is arranged on the side of the electron injection layer away from the substrate.

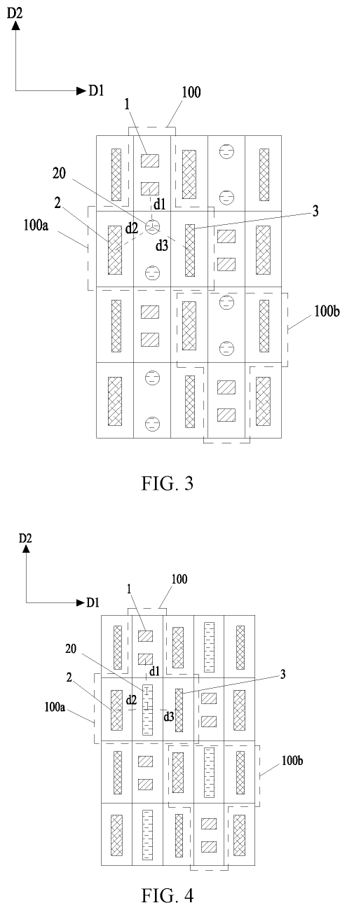

FIG. 3 is a second top view of a display panel according to an implementation of the present disclosure. In an exemplary implementation, as shown in FIG. 3, a functional unit 100 includes a pixel unit including two green sub-pixels 1, a blue sub-pixel 2, and a red sub-pixel 3, and two non-display units 20. Two green sub-pixels 1 are arranged along the second direction D2 of the substrate to form a green sub-pixel column, and the centers of the two green sub-pixels 1 are in a straight line along the second direction D2 of the substrate. The two non-display units 20 are arranged along the second direction D2 of the substrate to form a non-display unit column, and the centers of the two non-display units 20 are in a straight line along the second direction D2 of the substrate. In the first direction D1 of the substrate, the blue sub-pixel 2 and the red sub-pixel 3 are located on two sides of the non-display unit column, and the centers of the blue sub-pixel 2, the red sub-pixel 3 and the non-display unit column are in a straight line in the first direction D1 of the substrate. In the second direction D2 of the substrate, the green sub-pixel column is located on one side of the non-display unit column, and the center of the green sub-pixel column and the center of the non-display unit column are in a straight line in the second direction D2 of the substrate. Herein, the first direction D1 is different from the second direction D2. In an example, the first direction D1 is provided perpendicularly to the second direction D2. The orthographic projection of the non-display unit 20 on the substrate in the display panel of the implementation of the present disclosure is circular.

In some implementations, the orthographic projection of the non-display unit 20 on the substrate in the display panel of the implementation of the present disclosure may also be of other shapes, for example, the orthographic projection of the non-display unit 20 on the substrate in the display panel of the implementation of the present disclosure may be of regular or irregular shapes such as rectangle, diamond, ellipse, etc.

In an exemplary implementation, as shown in FIG. 3, the display panel according to an implementation of the present disclosure includes at least two functional units 100, the at least two functional units 100 are arranged along a first direction D1 of the substrate to form a functional unit row, and in one functional unit row, the centers of non-display units 20 of at least three functional units are in the same straight line in the first direction D1.

In an exemplary implementation, as shown in FIG. 3, at least two functional unit 100 in a display panel of an implementation of the present disclosure are arranged along the second direction D2 of the substrate to form a functional unit column, in a functional unit column, a non-display unit 20 is provided between green sub-pixels 1 in adjacent functional units 100, so that in a functional unit column, the green sub-pixels 1 in adjacent functional units 100 are far apart, thereby providing a display effect.

In an exemplary implementation, in the non-display unit column of a functional unit in the display panel of the implementation of the present disclosure, the distance between the centers of adjacent non-display units is greater than or equal to 0.5 times of the functional unit spacing.

In an exemplary implementation, as shown in FIG. 3, in the one functional unit, the minimum distance from the center of the at least one non-display unit 20 to the center of the at least one green sub-pixel 1 is d1, the minimum distance from the center of the at least one non-display unit 20 to the center of the at least one blue sub-pixel 2 is d2, and the minimum distance from the center of the at least one non-display unit 20 to the center of the at least one red sub-pixel 3 is d3, wherein d1, the d2 and the d3 satisfy the relation: d1 is greater than or equal to d2, and d1 is greater than or equal to d3.

In an exemplary implementation, in a functional unit, a non-display unit 20 is orthogonally projected on the substrate with an area greater than 100 square microns, thereby improving the functional effect of the non-display unit 20.

In an exemplary implementation, as shown in FIG. 3, the display panel of the implementation of the present disclosure may include at least one first functional unit 100a and at least one second functional unit 100b, which are arranged along the first direction D1 of the substrate to form a repeating unit. In a repeating unit, in the second direction D2 of the substrate, the green sub-pixel column in the first functional unit 100a is located on the first side of the non-display unit column, and the center of the green sub-pixel column in the first functional unit 100a is in a straight line with the center of the blue sub-pixel 2, the center of the red sub-pixel 3 and the center of the non-display unit column in the second functional unit 100b in the first direction D1 of the substrate. The green sub-pixel column in the second functional unit 100b is located on the second side of the non-display unit column, and the center of the green sub-pixel column in the second functional unit 100b is in a straight line with the center of the blue sub-pixel 2, the center of the red sub-pixel 3 and the center of the non-display unit column in the first functional unit 100a in the first direction D1 of the substrate. In the second direction D2 of the substrate, the first side of the non-display unit column and the second side of the non-display unit column are respectively located on opposite sides of the non-display unit column.

In an exemplary implementation, as shown in FIG. 3, a first functional unit 100a is arranged in a pyramid, a second functional unit 100b is arranged in an inverted pyramid, and a first functional unit 100a and a second functional unit 100b are arranged in combination to form a repeating unit. The display panel of an implementation of the present disclosure may include at least two repeating units arranged along the first direction D1 of the substrate to form a repeating unit row, and at least two repeating unit rows arranged along the second direction D2 of the substrate.

FIG. 4 is a third top view of a display panel according to an implementation of the present disclosure. In an exemplary implementation, as shown in FIG. 4, a functional unit 100 includes a pixel unit including two green sub-pixels 1, a blue sub-pixel 2, and a red sub-pixel 3, and a non-display units 20. Two green sub-pixels 1 are arranged along the second direction D2 of the substrate to form a green sub-pixel column, and the centers of the two green sub-pixels 1 are in a straight line along the second direction D2 of the substrate. In the first direction D1 of the substrate, the blue sub-pixel 2 and the red sub-pixel 3 are located on two sides of the non-display unit 20, and the centers of the blue sub-pixel 2, the red sub-pixel 3 and the non-display unit 20 are in a straight line in the first direction D1 of the substrate. In the second direction D2 of the substrate, the green sub-pixel column is located on one side of the non-display unit column, and the center of the green sub-pixel column and the center of the non-display unit 20 are in a straight line in the second direction D2 of the substrate. Herein, the first direction D1 is different from the second direction D2. In an example, the first direction D1 is provided perpendicularly to the second direction D2.

In an exemplary implementation, as shown in FIG. 4, the display panel according to an implementation of the present disclosure includes at least two functional units 100, the at least two functional units 100 are arranged along a first direction D1 of the substrate to form a functional unit row, and in one functional unit row, the centers of non-display units 20 of at least three functional units are in the same straight line in the first direction D1, thereby ensuring the fingerprint identification effect.

In an exemplary implementation, as shown in FIG. 4, at least two functional unit 100 in a display panel of an implementation of the present disclosure are arranged along the second direction D2 of the substrate to form a functional unit column, in a functional unit column, a non-display unit 20 is provided between green sub-pixels 1 in adjacent functional units 100, so that in a functional unit column, the green sub-pixels 1 in adjacent functional units 100 are far away, thereby providing a display effect.

In an exemplary implementation, as shown in FIG. 4, in the one functional unit, the minimum distance from the center of the at least one non-display unit 20 to the center of the at least one green sub-pixel 1 is d1, the minimum distance from the center of the at least one non-display unit 20 to the center of the at least one blue sub-pixel 2 is d2, and the minimum distance from the center of the at least one non-display unit 20 to the center of the at least one red sub-pixel 3 is d3, wherein d1, the d2 and the d3 satisfy the relation: d1 is greater than or equal to d2, and d1 is greater than or equal to d3.

In an exemplary implementation, in a functional unit, a non-display unit 20 is orthogonally projected on the substrate with an area greater than 100 square microns.

In an exemplary implementation, as shown in FIG. 4, the display panel of the implementation of the present disclosure may include at least one first functional unit 100a and at least one second functional unit 100b, which are arranged along the first direction D1 of the substrate to form a repeating unit. In a repeating unit, in the second direction D2 of the substrate, the green sub-pixel column in the first functional unit 100a is located on the first side of the non-display unit 20, and the center of the green sub-pixel column in the first functional unit 100a is in a straight line with the center of the blue sub-pixel 2, the center of the red sub-pixel 3 and the center of the non-display unit 20 in the second functional unit 100b in the first direction D1 of the substrate. The green sub-pixel column in the second functional unit 100b is located on the second side of the non-display unit 20, and the center of the green sub-pixel column in the second functional unit 100b is in a straight line with the center of the blue sub-pixel 2, the center of the red sub-pixel 3 and the center of the non-display unit 20 in the first functional unit 100a in the first direction D1 of the substrate. In the second direction D2 of the substrate, the first side of the non-display unit 20 and the second side of the non-display unit 20 are respectively located on opposite sides of the non-display unit 20.

In an exemplary implementation, as shown in FIG. 4, a first functional unit 100a is arranged in a pyramid, a second functional unit 100b is arranged in an inverted pyramid, and a first functional unit 100a and a second functional unit 100b are arranged in combination to form a repeating unit. The display panel of an implementation of the present disclosure may include at least two repeating units arranged along the first direction D1 of the substrate to form a repeating unit row, and at least two repeating unit rows arranged along the second direction D2 of the substrate.

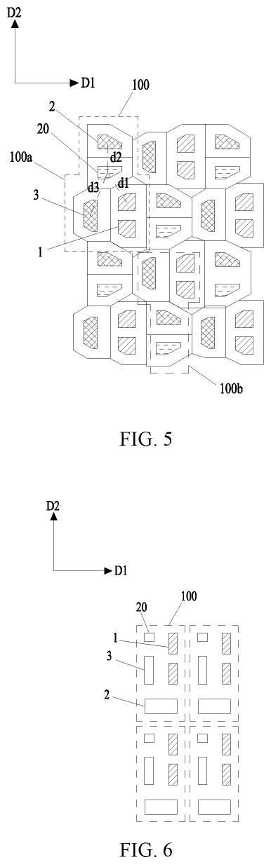

FIG. 5 is a fourth top view of a display panel according to an implementation of the present disclosure. In an exemplary implementation, as shown in FIG. 5, a functional unit 100 includes a pixel unit including two green sub-pixels 1, a blue sub-pixel 2, and a red sub-pixel 3, and a non-display units 20. Two green sub-pixels 1 are arranged along the second direction D2 of the substrate to form a green sub-pixel column, and the centers of the two green sub-pixels 1 are in a straight line along the second direction D2 of the substrate. The red sub-pixels 3 and the green sub-pixel column are arranged along the first direction D1 of the substrate to form a combined pixel row, and the centers of the red sub-pixels 3 and the green sub-pixel column are in a straight line along the first direction D1 of the substrate. In the second direction D2 of the substrate, the combined pixel row and the blue sub-pixel 2 are located on two sides of the non-display unit 20, and the center of the blue sub-pixel 2 and the center of the non-display unit 20 are in a straight line along the second direction D2 of the substrate. Herein, the first direction D1 is different from the second direction D2. In an example, the first direction D1 is provided perpendicularly to the second direction D2.

In an exemplary implementation as shown in FIG. 5, at least one of the green sub-pixel 1, the blue sub-pixel 2, the red sub-pixel 3, and the non-display unit 20 is orthogonally projected as a polygon on the substrate. For example, the orthographic projections of the green sub-pixel 1, the blue sub-pixel 2, the red sub-pixel 3, and the non-display unit 20 on the substrate are all pentagons.

In an exemplary implementation, as shown in FIG. 5, the display panel according to an implementation of the present disclosure includes at least two functional units 100, the at least two functional units 100 are arranged along a first direction D1 of the substrate to form a functional unit row, and in one functional unit row, the centers of non-display units 20 of at least three functional units are on the same straight line in the first direction D1, thereby ensuring the fingerprint identification effect.

In an exemplary implementation, as shown in FIG. 5, at least two functional unit 100 in a display panel of an implementation of the present disclosure are arranged along the second direction D2 of the substrate to form a functional unit column, in a functional unit column, a blue sub-pixel 2, a red sub-pixel 3, and a non-display unit 20 is provided between green sub-pixels 1 in adjacent functional units 100, so that in a functional unit column, the green sub-pixels 1 in adjacent functional units 100 are far away, thereby providing a display effect.

In an exemplary implementation, as shown in FIG. 5, in the one functional unit, the minimum distance from the center of the at least one non-display unit 20 to the center of the at least one green sub-pixel 1 is d1, the minimum distance from the center of the at least one non-display unit 20 to the center of the at least one blue sub-pixel 2 is d2, and the minimum distance from the center of the at least one non-display unit 20 to the center of the at least one red sub-pixel 3 is d3, wherein d1, the d2 and the d3 satisfy the relation: d1 is greater than or equal to d2, and d1 is greater than or equal to d3.

In an exemplary implementation, in a functional unit, a non-display unit 20 is orthogonally projected on the substrate with an area greater than 100 square microns, thereby improving the fingerprint identification effect.

In an exemplary implementation, as shown in FIG. 5, the display panel of the implementation of the present disclosure may include at least one first functional unit 100a and at least one second functional unit 100b, which are arranged along the first direction D1 of the substrate to form a repeating unit. In one repeating unit, the blue sub-pixel 2 and the non-display unit 20 in the first functional unit 100a are located on the first side of the combined pixel row in the second direction D2 of the substrate. The blue sub-pixel 2 and the non-display unit 20 in the second functional unit 100b are located on the second side of the combined pixel row. In the second direction D2 of the substrate, the first side of the combined pixel row and the second side of the combined pixel row are respectively located on opposite sides of the combined pixel row.

In an exemplary implementation, as shown in FIG. 5, a first functional unit 100a is arranged in a pyramid, a second functional unit 100b is arranged in an inverted pyramid, and a first functional unit 100a and a second functional unit 100b are arranged in combination to form a repeating unit. The display panel of an implementation of the present disclosure may include at least two repeating units arranged along the first direction D1 of the substrate to form a repeating unit row, and at least two repeating unit rows arranged along the second direction D2 of the substrate.

FIG. 6 is a fifth top view of a display panel according to an implementation of the present disclosure. In an exemplary implementation, as shown in FIG. 6, a functional unit 100 includes a pixel unit including two green sub-pixels 1, a blue sub-pixel 2, and a red sub-pixel 3, and a non-display units 20. Two green sub-pixels 1 are arranged along the second direction D2 of the substrate to form a green sub-pixel column, and the centers of the two green sub-pixels 1 are in a straight line along the second direction D2 of the substrate. The non-display unit 20 and the red sub-pixel 3 are arranged along the second direction D2 of the substrate to form a combined pixel column, and the centers of the non-display unit 20 and the red sub-pixel 3 are in a straight line along the second direction D2 of the substrate. The green sub-pixel column and the combined pixel column are arranged along the first direction D1 of the substrate, and the centers of the green sub-pixel column and the combined pixel column are in a straight line along the first direction D1 of the substrate. In the second direction D2 of the substrate, the green sub-pixel column and the combined pixel column are located on the same side of the blue sub-pixel 2. Herein, the first direction D1 is different from the second direction D2. In an example, the first direction D1 is provided perpendicularly to the second direction D2.

In an exemplary implementation, as shown in FIG. 6, the display panel according to an implementation of the present disclosure includes at least two functional units 100, the at least two functional units 100 are arranged along a first direction D1 of the substrate to form a functional unit row, and in one functional unit row, the centers of non-display units 20 of at least three functional units are in the same straight line in the first direction D1, thereby ensuring the fingerprint identification effect.

In an exemplary implementation, as shown in FIG. 6, at least two functional unit 100 in a display panel of an implementation of the present disclosure are arranged along the second direction D2 of the substrate to form a functional unit column, in a functional unit column, a blue sub-pixel 2 is provided between green sub-pixels 1 in adjacent functional units 100, so that in a functional unit column, the green sub-pixels 1 in adjacent functional units 100 are far apart, thereby providing a display effect.

In an exemplary implementation, in a functional unit, a non-display unit 20 is orthogonally projected on the substrate with an area greater than 100 square microns, thereby improving the fingerprint identification effect.

In an exemplary implementation, as shown in FIG. 6, a first functional unit 100 forms a repeating unit. The display panel of an implementation of the present disclosure may include at least two repeating units arranged along the first direction D1 of the substrate to form a repeating unit row, and at least two repeating unit rows arranged along the second direction D2 of the substrate.

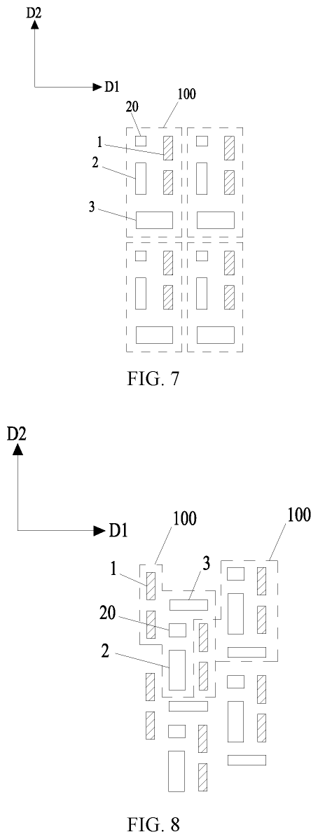

FIG. 7 is a sixth top view of a display panel according to an implementation of the present disclosure. In an exemplary implementation, as shown in FIG. 7, a functional unit 100 includes a pixel unit including two green sub-pixels 1, a blue sub-pixel 2 and a red sub-pixel 3, and a non-display units 20. Two green sub-pixels 1 are arranged along the second direction D2 of the substrate to form a green sub-pixel column, and the centers of the two green sub-pixels 1 are in a straight line along the second direction D2 of the substrate. The non-display unit 20 and the blue sub-pixel 2 are arranged along the second direction D2 of the substrate to form a combined pixel column, and the centers of the non-display unit 20 and the blue sub-pixel 2 are in a straight line along the second direction D2 of the substrate. The green sub-pixel column and the combined pixel column are arranged along the first direction D1 of the substrate, and the centers of the green sub-pixel column and the combined pixel column are in a straight line along the first direction D1 of the substrate. In the second direction D2 of the substrate, the green sub-pixel column and the combined pixel column are located on the same side of the red sub-pixel 3. Herein, the first direction D1 is different from the second direction D2. In an example, the first direction D1 is provided perpendicularly to the second direction D2.

In an exemplary implementation, as shown in FIG. 7, the display panel according to an implementation of the present disclosure includes at least two functional units 100, the at least two functional units 100 are arranged along a first direction D1 of the substrate to form a functional unit row, and in one functional unit row, the centers of non-display units 20 of at least three functional units are on the same straight line in the first direction D1, thereby ensuring the fingerprint identification effect.

In an exemplary implementation, as shown in FIG. 7, at least two functional unit 100 in a display panel of an implementation of the present disclosure are arranged along the second direction D2 of the substrate to form a functional unit column, in a functional unit column, a red sub-pixel 3 is provided between green sub-pixels 1 in adjacent functional units 100, so that in a functional unit column, the green sub-pixels 1 in adjacent functional units 100 are far apart, thereby providing a display effect.

In an exemplary implementation, in a functional unit, a non-display unit 20 is orthogonally projected on the substrate with an area greater than 100 square microns, thereby improving the fingerprint identification effect.

In an exemplary implementation, as shown in FIG. 7, a first functional unit 100 forms a repeating unit. The display panel of an implementation of the present disclosure may include at least two repeating units arranged along the first direction D1 of the substrate to form a repeating unit row, and at least two repeating unit rows arranged along the second direction D2 of the substrate.

FIG. 8 is a seventh top view of a display panel according to an implementation of the present disclosure. In an exemplary implementation, as shown in FIG. 8, a functional unit 100 includes a pixel unit and a non-display units 20, the pixel unit including four green sub-pixels 1, a blue sub-pixel 2, and a red sub-pixel 3. Two of the four green sub-pixels 1 are arranged along the second direction D2 of the substrate to form a green sub-pixel column a, and the centers of the two green sub-pixels 1 in the green sub-pixel column a are in a straight line along the second direction D2 of the substrate. The other two of the four green sub-pixels 1 are arranged along the second direction D2 of the substrate to form a green sub-pixel column b, and the centers of the two green sub-pixels 1 in the green sub-pixel column b are in a straight line along the second direction D2 of the substrate. The non-display unit 20 and the blue sub-pixel 2 are arranged along the second direction D2 of the substrate to form a combined pixel column, and the centers of the non-display unit 20 and the blue sub-pixel 2 in the combined pixel column are in a straight line along the second direction D2 of the substrate. The green sub-pixel column a and the combined pixel column are arranged in the first direction D1 of the substrate, and the centers of the green sub-pixel column a and the combined pixel column are in a straight line along the first direction D1 of the substrate. The red sub-pixel 3 is located on one side of the green sub-pixel column a and the combined pixel column in the second direction D2 of the substrate, and the green sub-pixel column b is located on one side of the red sub-pixel 3 and the non-display unit 20 in the first direction D1 of the substrate. Herein, the first direction D1 is different from the second direction D2. In an example, the first direction D1 is provided perpendicularly to the second direction D2.

In an exemplary implementation, the display panel of the implementation of the present disclosure includes at least two functional units 100, the at least two functional units 100 are arranged along the first direction D1 of the substrate to form a functional unit row, and in one functional unit row, the centers of non-display units 20 of at least three functional units are on the same straight line in the first direction D1, thereby ensuring the fingerprint identification effect.

In an exemplary implementation, adjacent functional units in a row of functional units share a green sub-pixel column a or a green sub-pixel column b.

In an exemplary implementation, at least two functional unit 100 in a display panel of an implementation of the present disclosure are arranged along the second direction D2 of the substrate to form a functional unit column, in a functional unit column, a red sub-pixel 3 is provided between green sub-pixels 1 in adjacent functional units 100, so that in a functional unit column, the green sub-pixels 1 in adjacent functional units 100 are far away, thereby providing a display effect.

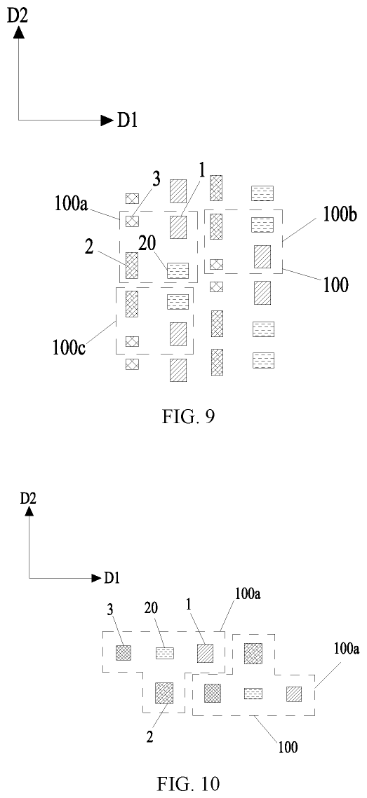

FIG. 9 is an eighth top view of a display panel according to an implementation of the present disclosure. In an exemplary implementation, as shown in FIG. 9, a functional unit 100 includes a pixel unit including a green sub-pixels 1, a blue sub-pixel 2, and a red sub-pixel 3, and a non-display units 20. The blue sub-pixel 2 and the non-display unit 20 are arranged along the first direction D1 of the substrate to form a first combined pixel row, and the red sub-pixel 3 and the green sub-pixel 1 are arranged along the first direction D1 of the substrate to form a second combined pixel row, in the second direction D2 of the substrate, the first combined pixel row is located on one side of the second combined pixel row. Herein, the first direction D1 is different from the second direction D2. In an example, the first direction D1 is provided perpendicularly to the second direction D2.

In an exemplary implementation, as shown in FIG. 9, the display panel of the implementation of the present disclosure may include at least one first functional unit 100a and at least one second functional unit 100b, which are arranged along the first direction D1 of the substrate to form a first repeating unit. In a first repeating unit, the first combined pixel row in the first functional unit 100a is located on the first side of the second combined pixel row in the second direction D2 of the substrate; the first combined pixel row in the second functional unit 100b is located on the second side of the second combined pixel row; wherein the first side of the second combined pixel row and the second side of the second combined pixel row are respectively located on opposite sides of the second combined pixel row. In some implementations, in a first repeating unit, the center of the first combined pixel row in the first functional unit 100a and the center of the second combined pixel row in the second functional unit 100b are in a straight line in the first direction D1 of the substrate. The center of the second combined pixel row in the first functional unit 100a and the center of the first combined pixel row in the second functional unit 100b are in a straight line in the first direction D1 of the substrate.

In an exemplary implementation, as shown in FIG. 9, the display panel of the implementation of the present disclosure may include at least one first functional unit 100a and at least one third functional unit 100c, and the first functional unit 100a and the third functional unit 100c are arranged along the second direction D2 of the substrate to form a second repeating unit. In a second repeating unit, the first combined pixel row in the first functional unit 100a is located on the first side of the second combined pixel row in the second direction D2 of the substrate; the first combined pixel row in the third functional unit 100c is located on the second side of the second combined pixel row; wherein the first side of the second combined pixel row and the second side of the second combined pixel row are respectively located on opposite sides of the second combined pixel row.

FIG. 10 is a ninth top view of a display panel according to an implementation of the present disclosure. In an exemplary implementation, as shown in FIG. 10, a functional unit 100 includes a pixel unit including a green sub-pixels 1, a blue sub-pixel 2 and a red sub-pixel 3, and a non-display units 20. In the first direction D1 of the substrate, the green sub-pixel 1 and the red sub-pixel 3 are located on two sides of the non-display unit 20, and the centers of the green sub-pixel 1, the red sub-pixel 3 and the non-display unit 20 are in a straight line in the first direction D1 of the substrate. In the second direction D2 of the substrate, the blue sub-pixel 2 is located on one side of the non-display unit 20, and the centers of the blue sub-pixel 2 and the non-display unit 20 are in a straight line in the second direction D2 of the substrate. Herein, the first direction D1 is different from the second direction D2. In an example, the first direction D1 is provided perpendicularly to the second direction D2.

In an exemplary implementation, as shown in FIG. 10, the display panel of the implementation of the present disclosure may include at least one first functional unit 100a and at least one second functional unit 100b, which are arranged along the first direction D1 of the substrate to form a repeating unit. In a repeating unit, in the second direction D2 of the substrate, the blue sub-pixel 2 in the first functional unit 100a is located on the first side of the non-display unit 20, and the center of the blue sub-pixel 2 in the first functional unit 100a is in a straight line with the center of the green sub-pixel 1, the center of the red sub-pixel 3 in the second functional unit 100b, and the center of the non-display unit 20 in the first direction D1 of the substrate. The blue sub-pixel 2 in the second functional unit 100b is located on the second side of the non-display unit 20, and the blue sub-pixel 2 in the second functional unit 100b is in a straight line with the centers of the green sub-pixel 1, the red sub-pixel 3 and the non-display unit 20 in the first direction D1 of the substrate. In the second direction D2 of the substrate, the first side of the non-display unit 20 and the second side of the non-display unit 20 are respectively located on opposite sides of the non-display unit 20.

In an exemplary implementation, as shown in FIG. 10, a first functional unit 100a is arranged in an inverted pyramid, a second functional unit 100b is arranged in a pyramid, and a first functional unit 100a and a second functional unit 100b are arranged in combination to form a repeating unit. The display panel of an implementation of the present disclosure may include at least two repeating units arranged along the first direction D1 of the substrate to form a repeating unit row, and at least two repeating unit rows arranged along the second direction D2 of the substrate.

An implementation of the present disclosure further provides a method for preparing a display panel, including:

forming at least one functional unit on a substrate, wherein the one functional unit includes a pixel unit and at least one non-display unit, the pixel unit includes at least one sub-pixel, the orthographic projection of the pixel unit on the substrate and the orthographic projection of the at least one non-display unit on the substrate are not overlapped.

The display panel of the implementation of the present disclosure includes at least two functional units 100, one functional unit 100 includes a pixel unit and at least one non-display unit 20, and the pixel unit includes at least one sub-pixel. Sub-pixels of the same color and/or non-display units 20 in adjacent functional units 100 are formed by the same evaporation process using the same mask.

In an exemplary implementation, in a stretching direction perpendicular to a mask, an interval L is provided between the extension line of the sub-pixel of the same color of one of two adjacent functional units 100 and/or an edge of the non-display unit 20 near the side of the other functional unit 100 and the extension line of the sub-pixel of the same color of the other functional unit 100 of two adjacent functional units 100 and/or the edge of the non-display unit 20 close to one side of the functional unit 100.

In an exemplary implementation, a functional unit includes a pixel unit and at least two non-display units. The pixel unit includes at least two green sub-pixels. The at least two green sub-pixels in a functional unit can be formed by evaporation through the same opening in a mask. At least two non-display units 20 in one functional unit 100 may be formed by evaporation of the same opening in one mask.

In an exemplary implementation, green sub-pixels in at least two functional units may be formed by simultaneous evaporation through different openings in the same mask. Blue sub-pixels in at least two functional units can be formed by simultaneous evaporation through different openings in the same mask. Red sub-pixels in at least two functional units can be formed by simultaneous evaporation through different openings in the same mask. Non-display units of at least two functional units can be formed by simultaneous evaporation through different openings in the same mask.

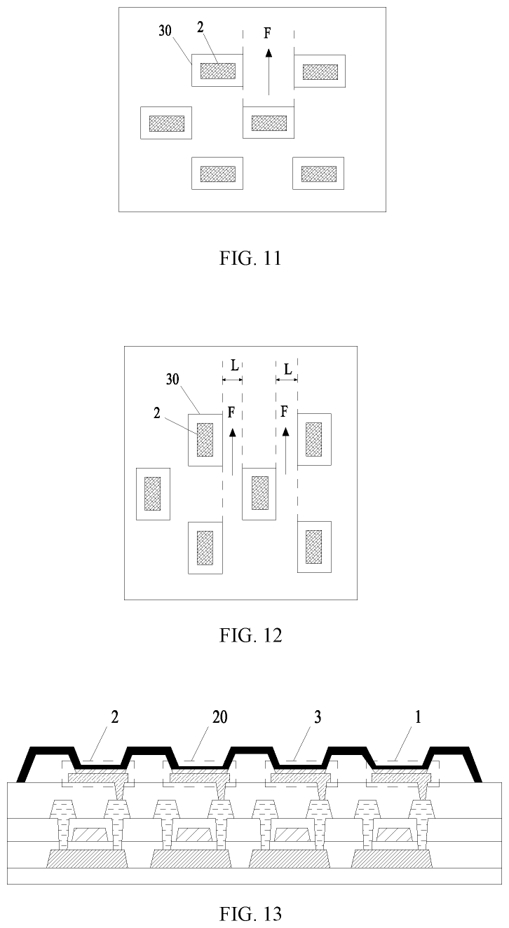

FIG. 11 is a first top view of a mask according to an implementation of the present disclosure. In an exemplary implementation, as shown in FIG. 11, the implementation of the present disclosure provides a mask including a mask body and at least two openings 30 disposed in the mask body, each opening 30 in one mask is a sub-pixel or non-display unit for forming the same brightness in the display panel of the implementation of the present disclosure. For example, each opening 30 in one mask is used to form a blue sub-pixel in the display panel of the implementation of the present disclosure, or each opening 30 in one mask is used to form a non-display unit in the display panel of the implementation of the present disclosure.

In an exemplary implementation, as shown in FIG. 11, one mask includes at least two openings 30, each opening 30 is used to form a blue sub-pixel in the display panel of the implementation of the present disclosure. Each opening 30 is rectangular. The long side of the opening 30 is perpendicular to the stretching direction of the mask, and the short side of the opening 30 is parallel to the stretching direction of the mask. In the stretching direction perpendicular to the mask, at least two openings 30 are arranged at intervals to form an opening row. In one opening row, the centers of adjacent openings 30 are not on the same straight line perpendicular to the stretching direction of the mask, that is, adjacent openings 30 are staggered from each other.

FIG. 12 is a second top view of a mask according to an implementation of the present disclosure. In an exemplary implementation, as shown in FIG. 12, one mask includes at least two openings 30, each opening 30 is used to form a blue sub-pixel in the display panel of the implementation of the present disclosure. Each opening 30 is rectangular. The long side of the opening 30 is parallel to the stretching direction of the mask, and the short side of the opening 30 is perpendicular to the stretching direction of the mask. In the stretching direction perpendicular to the mask, at least two openings 30 are arranged at intervals to form an opening row. In one opening row, the centers of adjacent openings 30 are not on the same straight line perpendicular to the stretching direction of the mask, that is, adjacent openings 30 are staggered from each other. In an opening row, two adjacent openings 30 are respectively a first opening 30a and a second opening 30b, and a space L is provided between the extension line of the edge of the first opening 30a close to the second opening 30b and the extension line of the edge of the second opening 30b close to the first opening 30a. When the mask of the implementation of the present disclosure is stretched, the tensile force F transmits the tensile force along the interval L, reducing the influence of the tensile force F on the deformation of the opening 30 and reducing the risk of mask wrinkling.

An implementation of the present disclosure further provides a display apparatus, including the aforementioned display panel. The display apparatus includes a mobile phone, a tablet computer, a smart wearable product (such as a smart watch, a bracelet, or the like), a personal digital assistant (PDA), a vehicle-mounted computer, or the like. A specific form of the above foldable display apparatus is not specially limited in the implementations of the present application.

The drawings of the present disclosure only involve structures involved in the present disclosure, and other structures may refer to conventional designs. The implementations in the present disclosure, i.e., features in the implementations, may be combined with each other to obtain new implementations if there is no conflict.

Those of ordinary skills in the art should understand that modifications or equivalent replacements of the technical solutions of the present disclosure may be made without departing from the spirit and scope of the technical solutions of the present disclosure, and shall all fall within the scope of the claims of the present disclosure.

1. A display panel, comprising a display region, wherein the display region comprises at least one functional unit disposed on a substrate, the one functional unit comprises a pixel unit and at least one non-display unit, wherein the pixel unit comprises at least one sub-pixel, and an orthographic projection of the pixel unit on the substrate does not overlap an orthographic projection of the at least one non-display unit on the substrate.

2. The display panel according to claim 1, wherein in the one functional unit, the pixel unit comprises at least one green sub-pixel, at least one blue sub-pixel and at least one red sub-pixel, a minimum distance from a center of the at least one non-display unit to a center of the at least one green sub-pixel is d1, a minimum distance from the center of the at least one non-display unit to a center of the at least one blue sub-pixel is d2, and a minimum distance from the center of the at least one non-display unit to a center of the at least one red sub-pixel is d3, wherein the d1, the d2 and the d3 satisfy a relation: d1 is greater than or equal to d2, and d1 is greater than or equal to d3.

3. The display panel according to claim 1, wherein the one functional unit comprises a pixel unit and at least two non-display units, the pixel unit comprises at least two green sub-pixels, one blue sub-pixel, and one red sub-pixel, and a quantity of the non-display units is the same as a quantity of the green sub-pixels.

4. The display panel according to claim 1, wherein the display panel comprises at least two functional units, the at least two functional units are arranged along a first direction of the substrate to form a functional unit row, and in one functional unit row, centers of non-display units of at least three functional units are in a same straight line in the first direction.

5. The display panel according to claim 1, wherein the one functional unit comprises a pixel unit and at least one non-display unit, the pixel unit comprises at least one green sub-pixel, at least one blue sub-pixel and at least one red sub-pixel, the display panel comprises at least two functional units, the at least two functional units are arranged along a second direction of the substrate to form a functional unit column, in one functional unit column, at least one of a blue sub-pixel, a red sub-pixel and a non-display unit is disposed between at least one green sub-pixel in adjacent functional units.

6. The display panel according to claim 1, wherein the one functional unit comprises at least two non-display units, at least two non-display units are arranged along a second direction of the substrate to form a non-display unit column, and a distance between centers of adjacent non-display units in one non-display unit column is greater than or equal to 0.5 times of functional unit spacing, wherein the functional unit spacing refers to a distance between centers of adjacent functional units.

7. The display panel according to claim 1, wherein in the one functional unit, an area of the orthographic projection of the at least one non-display unit on the substrate is greater than 100 square microns.

8. The display panel according to claim 1, wherein the non-display unit is an organic photodiode.

9. The display panel according to claim 1, wherein the one functional unit comprises a pixel unit and two non-display units, the pixel unit comprises two green sub-pixels, one blue sub-pixel and one red sub-pixel, the two green sub-pixels are arranged along a second direction of the substrate to form a green sub-pixel column, the two non-display units are arranged along the second direction of the substrate to form a non-display unit column, in a first direction of the substrate, the blue sub-pixel and the red sub-pixel are located on two sides of the non-display unit column, and in the second direction of the substrate, the green sub-pixel column is located on one side of the non-display unit column, wherein the first direction is different from the second direction.

10. The display panel according to claim 9, wherein the orthographic projection of the non-display unit on the substrate is at least one of a circle, a rectangle, a diamond, and an ellipse.

11. The display panel according to claim 1, wherein the one functional unit comprises a pixel unit and one non-display unit, the pixel unit comprises two green sub-pixels, one blue sub-pixel and one red sub-pixel, the two green sub-pixels are arranged along a second direction of the substrate to form a green sub-pixel column, in a first direction of the substrate, the blue sub-pixel and the red sub-pixel are located on two sides of the non-display unit, and in a second direction of the substrate, the green sub-pixel column is located on one side of the non-display unit column, wherein the first direction is different from the second direction.

12. The display panel according to claim 1, wherein the one functional unit comprises a pixel unit and one non-display unit, the pixel unit comprises two green sub-pixels, one blue sub-pixel and one red sub-pixel, the two green sub-pixels are arranged along a second direction of the substrate to form a green sub-pixel column, the red sub-pixel and the green sub-pixel columns are arranged along a first direction of the substrate to form a combined pixel row, in a second direction of the substrate, the combined pixel row and the blue sub-pixel are located on two sides of the non-display unit, wherein the first direction is different from the second direction.

13. The display panel according to claim 12, wherein an orthographic projection of at least one of the green sub-pixel, the blue sub-pixel, the red sub-pixel, and the non-display unit on the substrate is a polygon.

14. The display panel according to claim 1, wherein the one functional unit comprises a pixel unit and one non-display unit, the pixel unit comprises two green sub-pixels, one blue sub-pixel and one red sub-pixel, the two green sub-pixels are arranged along a second direction of the substrate to form a green sub-pixel column, the non-display unit and the red sub-pixel are arranged in the second direction of the substrate to form a combined pixel column, the green sub-pixel column and the combined pixel column are arranged along a first direction of the substrate, and in the second direction of the substrate, the green sub-pixel column and the combined pixel column are located on a same side of the blue sub-pixel, wherein the first direction is different from the second direction.

15. The display panel according to claim 1, wherein the one functional unit comprises a pixel unit and one non-display unit, the pixel unit comprises two green sub-pixels, one blue sub-pixel and one red sub-pixel, the two green sub-pixels are arranged along a second direction of the substrate to form a green sub-pixel column, the non-display unit and the blue sub-pixel are arranged along the second direction of the substrate to form a combined pixel column, the green sub-pixel column and the combined pixel column are arranged along a first direction of the substrate, and the green sub-pixel column and the combined pixel column are located on a same side of the red sub-pixel in the second direction of the substrate.

16. The display panel according to claim 1, wherein the one functional unit comprises a pixel unit and one non-display unit, the pixel unit comprises four green sub-pixels, one blue sub-pixel and one red sub-pixel, two of the four green sub-pixels are arranged along a second direction of the substrate to form a green sub-pixel column a, the other two of the four green sub-pixels are arranged along the second direction of the substrate to form a green sub-pixel column b, the non-display unit and the blue sub-pixel are arranged along the second direction of the substrate to form a combined pixel column, the green sub-pixel column a and the combined pixel column are arranged in a first direction of the substrate, the red sub-pixel is located on one side of the green sub-pixel column a and the combined pixel column in the second direction of the substrate, and the green sub-pixel column b is located on one side of the red sub-pixel and the non-display unit in the first direction of the substrate, wherein the first direction is different from the second direction.

17. The display panel according to claim 1, wherein the one functional unit comprises a pixel unit and one non-display unit, the pixel unit comprises one green sub-pixel, one blue sub-pixel and one red sub-pixel, the blue sub-pixel and the non-display unit are arranged along a first direction of the substrate to form a first combined pixel row, the red sub-pixel and the green sub-pixel are arranged along the first direction of the substrate to form a second combined pixel row, and the first combined pixel row is located on one side of the second combined pixel row in a second direction of the substrate, wherein the first direction is different from the second direction.

18. The display panel according to claim 17, wherein the display panel comprises at least two functional units arranged along the second direction of the substrate to form a functional unit column, in one functional unit column, the first combined pixel rows in adjacent functional units are adjacent in the second direction of the substrate; and/or, the second combined pixel rows in adjacent functional units are adjacent in the second direction of the substrate.

19. The display panel according to claim 1, wherein the one functional unit comprises a pixel unit and one non-display unit, the pixel unit comprises one green sub-pixel, one blue sub-pixel and one red sub-pixel, in a first direction of the substrate, the green sub-pixel and the red sub-pixel are located on two sides of the non-display unit, and in a second direction of the substrate, the blue sub-pixel is located on one side of the non-display unit, wherein the first direction is different from the second direction.

20. (canceled)

21. A method for preparing a display panel, comprising:
forming at least one functional unit on a substrate, wherein the one functional unit comprises a pixel unit and at least one non-display unit, the pixel unit comprises at least one sub-pixel, an orthographic projection of the pixel unit on the substrate and an orthographic projection of the at least one non-display unit on the substrate are not overlapped.

22. (canceled)
